(19) United States
(12) Patent Application Publication
(10) Pub. No.: US 2026/0139357 A1
(43) Pub. Date: May 21, 2026

(54) STRUCTURAL MEMBER

(71) Applicant: TOTO LTD., Fukuoka (JP)

(72) Inventors: Kenichi MOTOMURA, Fukuoka (JP); Ryoto TAKIZAWA, Fukuoka (JP)

(73) Assignee: TOTO LTD., Fukuoka (JP)

(21) Appl. No.: 19/310,441

(22) Filed: Aug. 26, 2025

(30) Foreign Application Priority Data
Nov. 20, 2024 (JP) 2024-202106

(51) Int. Cl. C23C 14/08

(52) U.S. Cl. CPC C23C 14/083

(57) ABSTRACT

A structural member 10 includes a substrate 100 and a passivation film 200 covering the surface 110 of the substrate 100. The passivation film 200 includes yttria as a main component, and the full width at half maximum of the peak at a wavenumber of approximately 370 cm⁻¹ in the Raman spectrum of the passivation film 200 obtained by Raman spectroscopy is 23 cm⁻¹ or more.

This application is based upon and claims the benefit of priority from Japanese Patent Application No. 2024-202106, filed on Nov. 20, 2024, the entire contents of which are incorporated herein by reference.

### FIELD

The present invention relates to a structural member.

### BACKGROUND

Structural members with a passivation film (protective film) on the surface of a substrate (base material) are used in various fields such as semiconductor manufacturing apparatus. For example, as disclosed in Japanese Patent Laid-Open No. 2007-321183, a passivation film for protecting a substrate from plasma is formed on the surface of the substrate forming the inner wall of a chamber in semiconductor manufacturing apparatus. Oxide ceramics such as yttria are used for such passivation film.

### SUMMARY

When substrates are repeatedly processed in semiconductor manufacturing apparatus, the passivation film degrades gradually over time. To reduce the frequency of maintenance for semiconductor manufacturing apparatus, it is desirable that the passivation film has a resistance (durability) against plasma as high as possible.

The present invention has been made in view of such problems, and an object of the present invention is to provide a structural member with a passivation film having high resistance against plasma.

To solve the above problem, the structural member of the present invention comprises a substrate and a passivation film covering the surface of the substrate. The passivation film comprises yttria as a main component, and the full width at half maximum of the peak at a wavenumber of approximately 370 cm⁻¹ in the Raman spectrum of the passivation film obtained by Raman spectroscopy is 23 cm⁻¹ or more.

The present inventors have found through experiments that the more disordered the atomic arrangement of the passivation film is, the higher the resistance of the passivation film against plasma. When the atomic arrangement of the passivation film is disordered such that the full width at half maximum described above is 23 cm⁻¹ or more, deterioration from the surface toward the back side of the passivation film is suppressed, and as a result, the resistance of the passivation film is considered to improve.

According to the present invention, a structural member with a passivation film having high resistance against plasma can be provided.

### BRIEF DESCRIPTION OF THE DRAWINGS

FIG. 1 schematically illustrates a cross-section of the structural member of the present embodiment;

FIGS. 2A and 2B are graphs for illustrating the Raman spectrum;

FIG. 3 is a graph for illustrating the Raman spectrum;

FIG. 4 is a table listing film-forming conditions when forming a passivation film and the full width at half maximum of the peak in the Raman spectrum; and

FIG. 5 is a graph illustrating the relationship between the full width at half maximum of the peak in the Raman spectrum and the resistance of the passivation film against plasma.

### DETAILED DESCRIPTION

Hereinafter the present embodiment will be described with reference to attached drawings. For clarity of description, identical reference numerals are used to denote the same elements in all figures, and redundant descriptions are omitted.

The structural member 10 of the present embodiment is configured as a member for a semiconductor manufacturing apparatus, such as a plasma etching apparatus. More specifically, the structural member 10 is a member used for the inner wall of a process chamber of semiconductor manufacturing apparatus. The use of the structural member 10 in the present embodiment is merely an example. The structural member 10 may be a member arranged within the process chamber of semiconductor manufacturing apparatus, such as a focus ring.

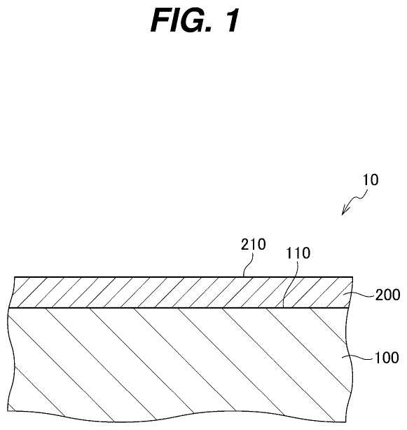

As shown in FIG. 1, the structural member 10 includes a substrate 100 and a passivation film 200. In a plasma etching apparatus or the like, the surface 210 of the passivation film 200 is exposed to the interior of the process chamber. The passivation film 200 is formed to protect the surface 110 of the substrate 100 from plasma.

The substrate 100 is a member forming the primary portion of the structural member 10. In the present embodiment, the substrate 100 is a sintered ceramic body including high-purity alumina (Al₂O₃) as a main component, but may be a different ceramic material or member other than a non-ceramic material (for example, a metal member). The surface 110 of the substrate 100 is flat in the present embodiment, but may be curved or tapered in portions.

The passivation film 200 is formed to protect the substrate 100 from plasma as described above. The passivation film 200 is formed to cover the entire surface 110 of the substrate 100. The passivation film 200 is composed of a material including yttria as a main component. Yttria described above is, for example, Y₂O₃. The ratio of the number of yttrium (Y) atoms to the number of oxygen (O) atoms in the passivation film 200 may be different from the ratio described above. The passivation film 200 of the present embodiment is formed by using a physical vapor deposition method (PVD), but may be formed by other film forming methods.

As used herein, the “main component” refers to the compound contained in the greatest amount in the target object (in this case, passivation film 200). More specifically, the “main component” refers to the compound contained in the greatest amount in terms of volume ratio or mass ratio relative to other compounds in the object, as determined by quantitative or semi-quantitative analysis using X-ray diffraction (XRD) on the object.

The proportion of the main component (yttria) in the passivation film 200 of the present embodiment is more than 50% by volume or by mass. The proportion may be more than 70%, more than 90%, or may be 100%.

The thickness of the passivation film 200 is appropriately adjusted depending on the duration for which resistance is required to be maintained and other factors. In the present embodiment, the passivation film 200 has a thickness of 20 μm or less.

The present inventors have used yttria as a material for the passivation film 200 as in the present embodiment, and have been considering further improvement in the resistance of the material against plasma. As a result, the present inventors have found a correlation between the profile of the Raman spectrum of the passivation film 200 obtained by Raman spectroscopy and the resistance of the passivation film 200 to plasma.

The Raman spectrum of the passivation film 200 was obtained by the following method. A laser Raman microscope manufactured by Nanophoton (RAMAN Imager 2) was used as a measurement apparatus. Using the apparatus, light with a wavelength of 532 nm was incident on the surface 210 of the passivation film 200 for 60 seconds, and the generated Raman scattered light (Stokes light) was detected and analyzed to obtain the Raman spectrum. The surface 210 was subjected to five cycles of 60-second light irradiation, and the Raman spectra from each measurement were averaged to obtain the final Raman spectrum.

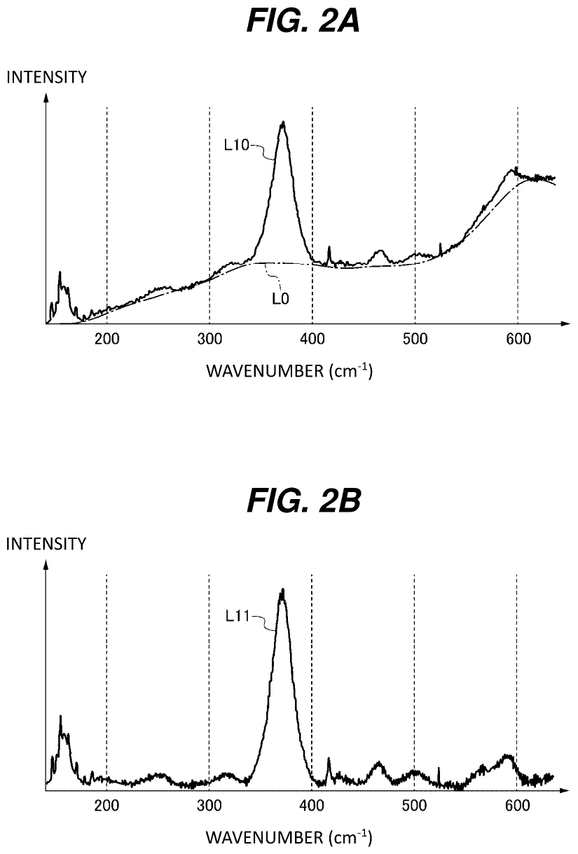

Line L10 in FIG. 2A is an example of the obtained Raman spectra. The horizontal axis of FIG. 2A represents the reciprocal of the wavelength of the detected Raman scattered light, namely, the wavenumber, in units of cm⁻¹. The vertical axis represents the intensity distribution of the Raman scattered light for each wavenumber. When the passivation film 200 includes yttria, as in the present embodiment, a large peak is observed at a wavenumber of approximately 370 cm⁻¹. Thus, to include the peak, data was obtained in the wavenumber range of 140 cm⁻¹ to 640 cm⁻¹.

The dash-dotted line L0 shown in FIG. 2A represents the background intensity in the absence of peaks, namely a profile of the baseline. The profile can be inferred, for example, from the overall profile of the Raman spectrum shown by the line L10.

The line L11 in FIG. 2B is obtained by applying a conversion processing to the profile of the Raman spectrum of the line L10 so that the dash-dotted line L0, which is the baseline, is flattened. In other words, the profile of the line L11 is obtained by subtracting each value of the dash-dotted line L0 from each value of the line L10. This processing, referred to as baseline correction, is often pre-installed as a standard software function.

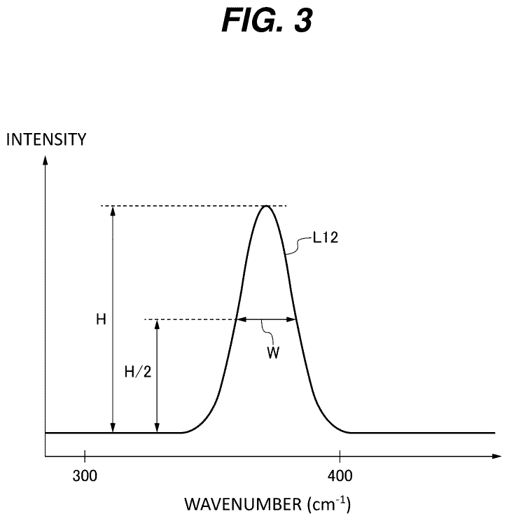

As shown in FIG. 2B, in the profile of the line L11 obtained by the baseline correction, a relatively large peak is observed at a wavenumber of approximately 370 cm⁻¹. When fitting is applied to the profile of the line L11 so that only this peak remains in a smooth profile, the profile represented by the line L12 in FIG. 3 is obtained. As such fitting, a known processing such as Gaussian fitting may be used.

When the maximum height of the peak in the line L12 is “H”, the width of the peak at a height of H/2, known as the “full width at half maximum”, is also referred to as “full width at half maximum W” below. The full width at half maximum W can be considered as the full width at half maximum of the peak at a wavenumber of approximately 370 cm⁻¹ in the Raman spectrum of the passivation film 200 obtained by Raman spectroscopy.

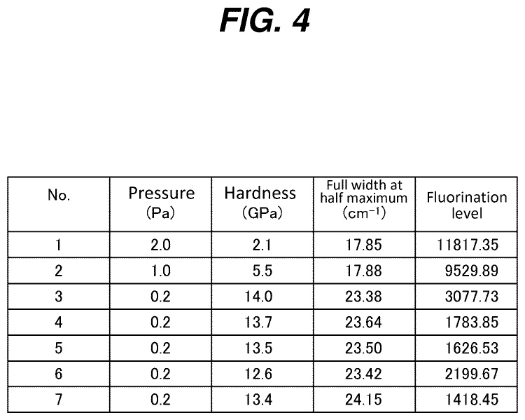

The present inventors prepared multiple samples of the structural member 10, measured the full width at half maximum W as described above, and evaluated the resistance of the passivation film 200 against plasma. A total of 7 samples of the structural member 10, Samples No. 1 to 7, were prepared. For all samples, the passivation film 200 was formed by using a physical vapor deposition method. The table in FIG. 4 shows the evaluation results and other conditions.

The “pressure” shown in FIG. 4 represents the pressure in the film forming chamber during the formation of the passivation film 200, in particular, the pressure of argon, in units of Pa.

The “hardness” shown in FIG. 4 represents the indentation hardness of the passivation film 200, expressed in units of GPa. The indentation hardness of the passivation film 200 was measured by performing a nanoindentation test for the surface 210 of the passivation film 200 formed on the substrate 100. The indentation hardness of the surface 210 was measured at several sites using a Berkovich indenter with an indentation depth fixed at 200 nm. The respective measurement sites were portions of the surface 210 free of scratches or pits. Provided that the surface 210 is polished to achieve a smooth finish before indentation hardness testing, measurements can be conducted with enhanced precision. The number of measurement sites was 10 or more, and the average of the indentation hardness values obtained from each site was determined as the indentation hardness value of the passivation film 200. For specific testing methods, analytical methods, procedures for verifying testing device performance, and requirements for reference samples, methods specified in ISO14577 were employed.

The “full width at half maximum” shown in FIG. 4 is the value of the full width at half maximum W described above. Raman spectra were obtained and the full width at half maximum W was calculated three times for each sample. The value of the full width at half maximum of each sample shown in FIG. 4 is obtained by averaging the three calculated full width at half maximum W values.

After measuring the indentation hardness and the full width at half maximum W of the passivation film 200, plasma resistance evaluation tests were performed for each sample. To evaluate the resistance of the passivation film 200, the surface 210 of each passivation film 200 was exposed to a plasma environment using an inductively coupling plasma reactive ion etching (ICP-RIE) system (not shown). The following conditions were employed when exposing the surface 210 to the plasma environment.

First, a 4-inch silicon wafer was held by an electrostatic chuck within the chamber of an inductively coupled plasma reactive ion etching system. Next, a sample of the structural member 10, the subject of evaluation, was placed on the silicon wafer. Subsequently, the surface 210 of the passivation film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 30 minutes. The power output was set to 1,500 W for the ICP coil and 750 W for the bias. By setting the bias output to 750 W, the plasma is drawn toward the passivation film 200, and used for the etching of the passivation film 200.

The “fluorination level” shown in FIG. 4 is an indicator of how deep fluorine atoms penetrate into the interior of the passivation film 200 when the passivation film 200 is exposed to a plasma atmosphere as described above. Specific measurement methods of the fluorination level are as follows.

First, while sputtering the surface 210 of the passivation film 200 after being exposed to a plasma atmosphere as described above using argon, the amount of fluorine atoms present on the surface 210 was continuously measured by X-ray photoelectron spectroscopy (XPS). The measurement was performed for 145 seconds. During the measurement, the proportion of the measured argon concentration in the overall composition (in %) was calculated at each time point, and the integrated value of these proportions was defined as the “fluorination level” of the sample. The higher the resistance of the passivation film 200 against plasma, the smaller the value of the fluorination level calculated as described above. The fluorination level may be used as an indicator of the resistance of the passivation film 200 against plasma.

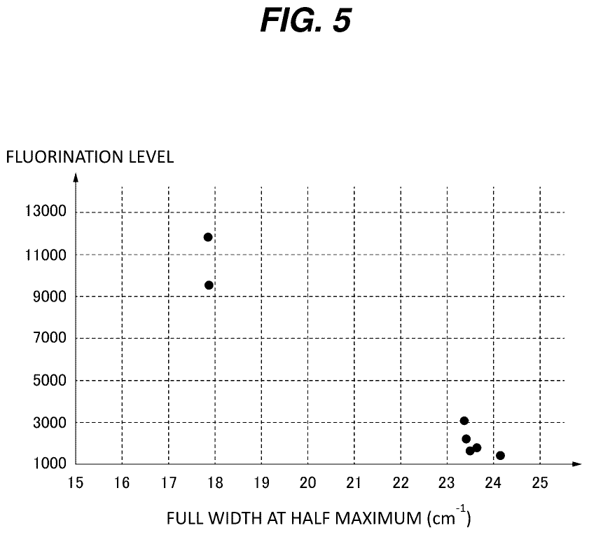

The relationship between the full width at half maximum W and the fluorination level is plotted in FIG. 5. As shown in FIG. 5, the larger the full width at half maximum W, the more the fluorination level of the passivation film 200 is reduced. In other words, FIG. 5 confirms that the larger the full width at half maximum W, the higher the resistance of the passivation film 200 against plasma. FIG. 5 indicates that the samples with a full width at half maximum of 23 cm⁻¹ or more have sufficiently reduced fluorine level and exhibit sufficient resistance against plasma.

The more disordered the atomic arrangement of the passivation film 200 is, the larger the full width at half maximum W value. When the atomic arrangement is disordered such that the full width at half maximum W is 23 cm⁻¹ or more, deterioration from the surface toward the back side of the passivation film 200 is suppressed, and as a result, the resistance of the passivation film 200 is considered to improve.

As shown in FIG. 4, all samples with a full width at half maximum W of 23 cm⁻¹ or more (Samples No. 3 to 7) were found to have an indentation hardness of the passivation film 200 of 12 GPa or more.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a substrate, and
a passivation film covering a surface of the substrate,
wherein the passivation film comprises yttria as a main component, and
a full width at half maximum of a peak at a wavenumber of approximately 370 cm⁻¹ in a Raman spectrum of the passivation film obtained by Raman spectroscopy is 23 cm⁻¹ or more.

2. The structural member according to claim 1, wherein the passivation film is formed by using a physical vapor deposition method.

3. The structural member according to claim 1, wherein the substrate comprises alumina as a main component.

4. The structural member according to claim 1, wherein the passivation film has an indentation hardness of 12 GPa or more.
